(19) United States
(12) Patent Application Publication
(10) Pub. No.: US 2011/0211141 A1
(43) Pub. Date: Sep. 1, 2011

(54) LIGHTING DEVICE, DISPLAY DEVICE AND TELEVISION RECEIVER

(75) Inventor: Shiyoshi Cho, Osaka-shi (JP)

(73) Assignee: SHARP KABUSHIKI KAISHA, Osaka-shi, Osaka (JP)

(21) Appl. No.: 13/127,984

(22) PCT Filed: Aug. 20, 2009
(86) PCT No.: PCT/JP2009/064555

§ 371 Date: May 6, 2011

(30) Foreign Application Priority Data
Dec. 5, 2008 (JP) 2008-311256

(51) Int. Cl. G02F 1/1335; H01L 33/10

(52) U.S. Cl. 349/61; 257/89; 257/E33.067

(57) ABSTRACT

A backlight unit 12 includes an LED 16 and light guide plates 18. The ELD includes a light emitting surface 16d. Each light guide plate includes a light entrance surface 18b and a light exit surface 18c. The light entrance surface 18b is provided to face the light emitting surface 16d and rays of light emitted from the light emitting surface 16d enter the light entrance surface 18b. The rays of light exit through the light exit surface 18c. The light guide plates are arranged parallel to each other along the light exit surface 18c. The light emitting surface 16d and the light entrance surface 18b are slanted to a surface perpendicular to the light exit surface 18c.

### TECHNICAL FIELD

The present invention relates to a lighting device, a display device and a television receiver.

### BACKGROUND ART

In recent years, displays of image display devices including television receivers are shifting from conventional cathode-ray tube displays to thin-screen displays including liquid crystal panels and plasma display panels. With the thin-screen displays, thin image display devices can be provided. A liquid crystal display device requires a backlight unit as a separate lighting device because a liquid crystal panel used therein is not a light-emitting component.

For example, a liquid crystal display device reducing its thickness and increasing its size disclosed in Patent Document 1 has been known. The liquid crystal display device includes light sources and light guide plates. The light sources emit rays of light in a direction substantially parallel to the display surface of the liquid crystal panel. Each of the light guide plates has a light entrance surface in its side-edge area and a light exit surface on its upper surface. The light entrance surface faces the light source and rays of light emitting from the light source strike the light entrance surface. The rays of light exit through the light exit surface toward the display surface of the liquid crystal panel. A number of sets each including the light guide plate and the light source are arranged parallel to each other in an arrangement direction and adjacent light guide plates partially overlap each other.

Patent Document 1: Japanese Published Patent Application No. 2001-93321

### PROBLEM TO BE SOLVED BY THE INVENTION

In the above-mentioned backlight unit, the adjacent light guide plates overlap each other for the following reason. If an LED having a number of LED chips each of which emits light of a single color is used as the light source, the rays of single color light emitted from each LED chip is required to be mixed while traveling through the light guide plate. In such a case, a certain light path length is necessarily ensured for the rays of light traveling through the light guide plate. Therefore, a light guide portion having no light exit surface may be provided on the light guide plate. If the light guide portion having no light exit surface is bare on the front-surface side, it may be recognized as a dark point. Therefore, the adjacent light guide plate is provided to overlap the light guide portion.

However, if the light guide plates are arranged to overlap each other, different problems may be caused. If any one of the LEDs has malfunction as a result of a lighting test after each of the light guide plate is arranged, not only the light guide plate corresponding to the LED having malfunction but also all the light guide plates that directly or indirectly overlap the light guide plate are required to be removed. This causes troublesome operations.

### DISCLOSURE OF THE PRESENT INVENTION

The present invention was made in view of the foregoing circumstances. An object of the present invention is to ensure a sufficient light path length of rays of light traveling through a light guide member without overlapping the light guide members.

### Means for Solving the Problem

A lighting device of the present invention includes a light source and a light guide member. The light source includes a light emitting surface. The light guide member includes a light entrance surface and a light exit surface. The light entrance surface is provided to face the light emitting surface and light emitted from the light emitting surface enters the light entrance surface. The light exits through the light exit surface. The light emitting surface and the light entrance surface are slanted to a surface perpendicular to the light exit surface.

With this configuration, the rays of light emitted from the light emitting surface of the light source and entering the light entrance surface of the light guide member are totally reflected by an interface between the light guide member and the external space and travel through the light guide member. Then, the rays of light exit from the light exit surface. The light emitting surface and the light entrance surface are slanted to a surface perpendicular to the light exit surface. Therefore, compared to the case in which the light emitting surface and the light entrance surface are provided to be perpendicular to the light exit surface, the rays of light traveling through the light guide member are able to be angled so that the number of reflection times at the interface relatively increases. This ensures a sufficient light path length of rays of light traveling through the light guide member. The adjacent light guide members are not required to overlap each other.

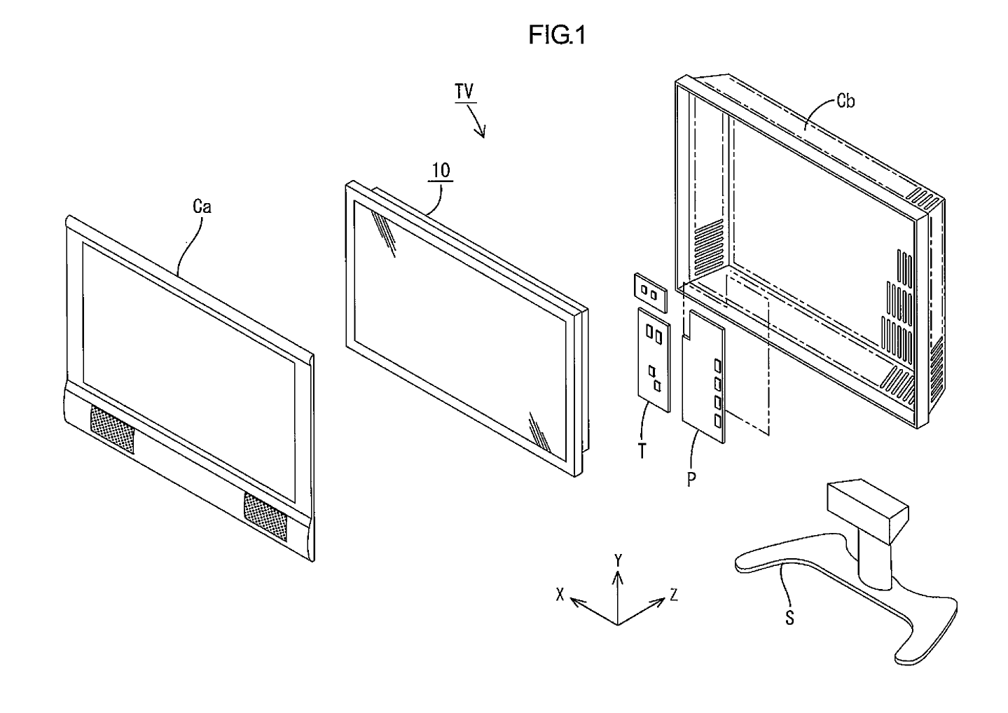

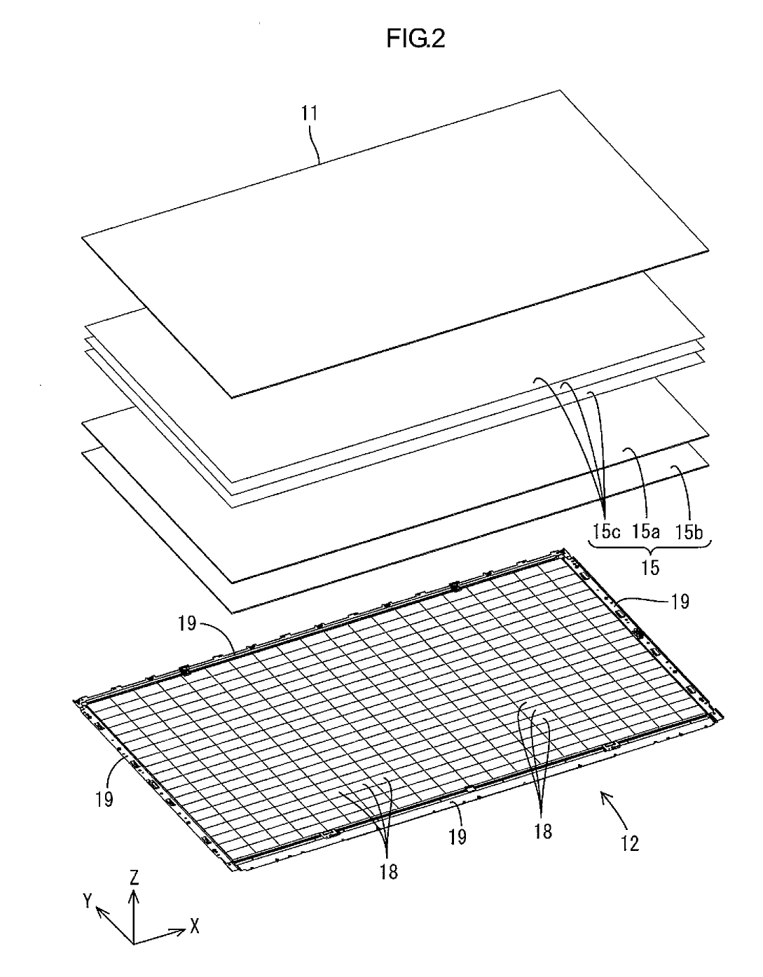

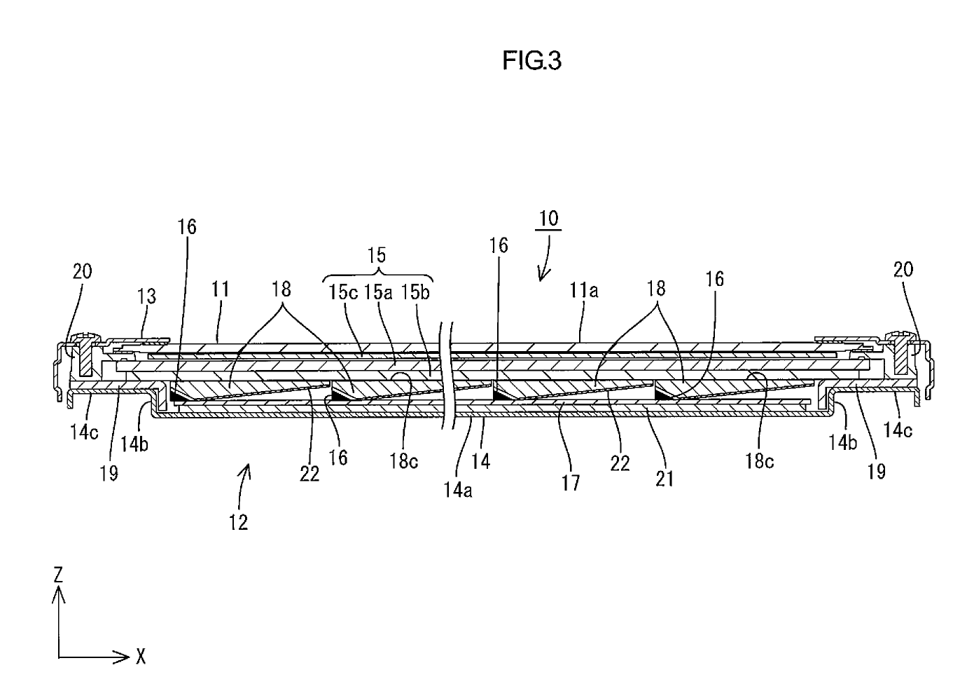

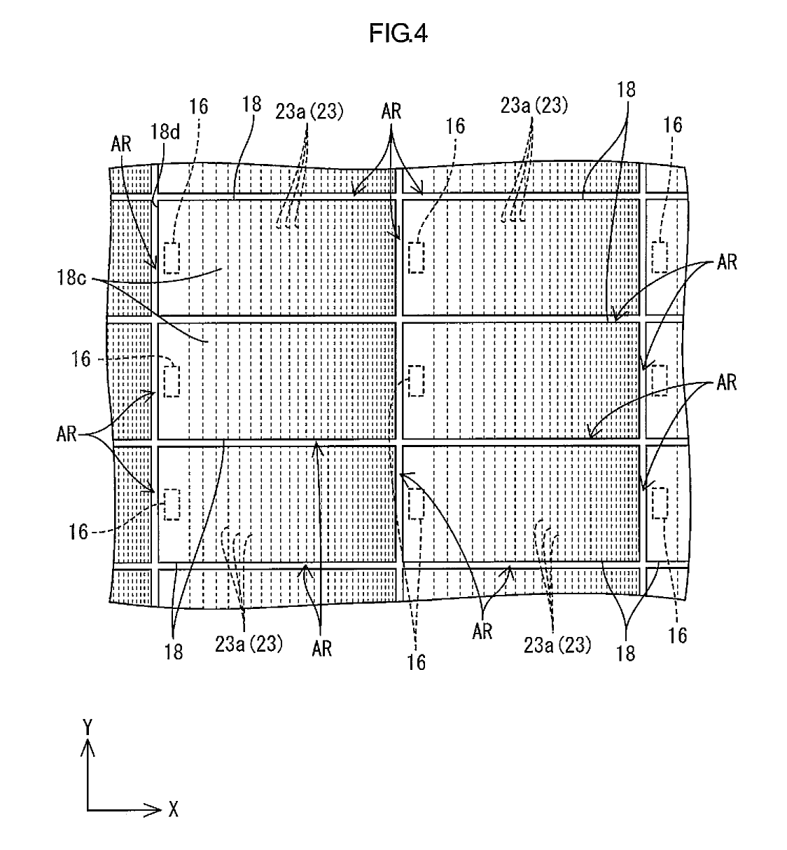

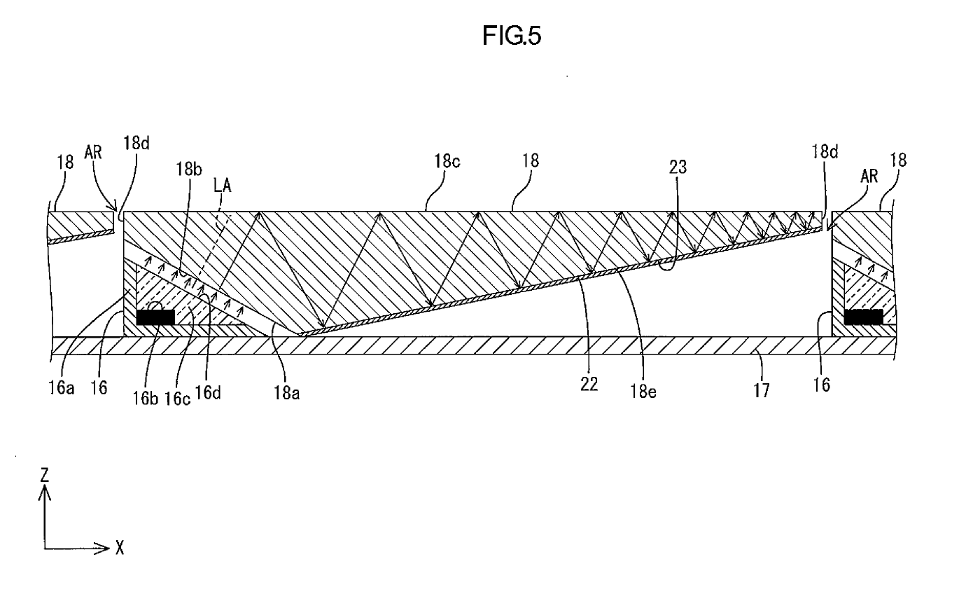

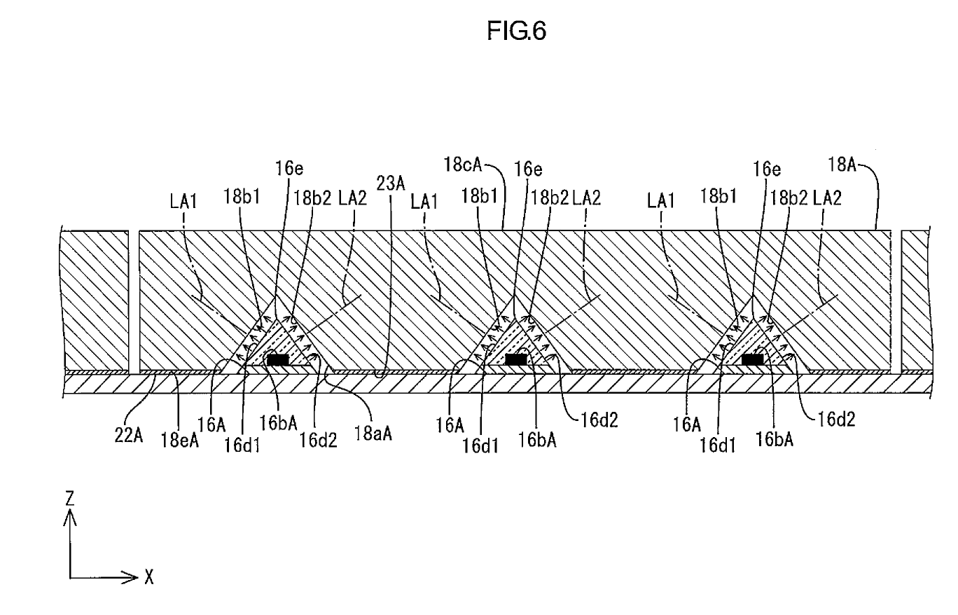

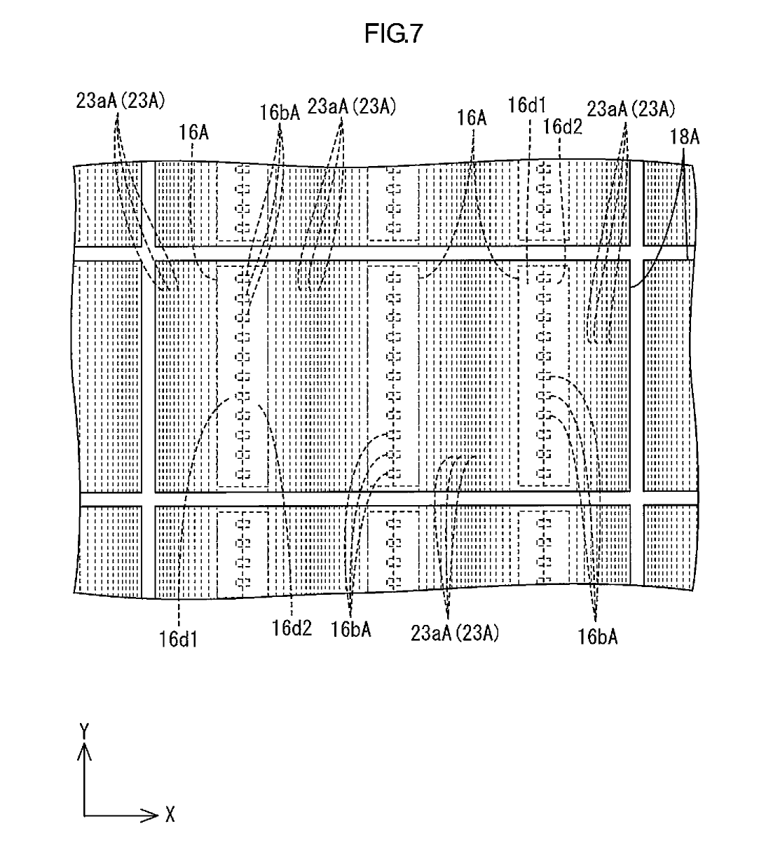

### BRIEF DESCRIPTION OF THE DRAWINGS

[FIG. 1] is an exploded perspective view illustrating a general construction of a television receiver according to the first embodiment of the present invention;

[FIG. 2] is an exploded perspective view illustrating a general construction of a liquid crystal panel and a backlight unit;

[FIG. 3] is a cross-sectional view of a liquid crystal display device along the long side thereof;

[FIG. 4] is a plan view illustrating a layout of the LEDs and the light guide plates;

[FIG. 5] is a cross-sectional view of an LED and a liquid crystal display device along the long side of the liquid crystal display device;

[FIG. 6] is a cross-sectional view of LEDs and light guide plates according to a second embodiment of the present invention; and

[FIG. 7] is a plan view illustrating a layout of the LEDs and the light guide plates.

### BEST MODE FOR CARRYING OUT THE INVENTION

### First Embodiment

The first embodiment of the present invention will be explained with reference to FIGS. 1 to 5. In this embodiment, a liquid crystal display device 10 will be explained. X-axes, Y-axes and Z-axes in some figures correspond to each other so as to indicate the respective directions. In FIGS. 2 and 3, the upper side and the lower side correspond to the front-surface side and the rear-surface side, respectively.

As illustrated in FIG. 1, the television receiver TV includes the liquid crystal display device 10 (a display device), cabinets Ca and Cb, a power source P, and a tuner T. The cabinets Ca and Cb sandwich the liquid crystal display device 10 therebetween. The liquid crystal display device 10 is housed in the cabinets Ca and Cb. The liquid crystal display device 10 is held by a stand S in a vertical position in which a display surface 11a is set along a substantially vertical direction (the Y-axis direction). The liquid crystal display device 10 has a landscape rectangular overall shape. As illustrated in FIG. 2, the liquid crystal display device 10 includes a liquid crystal panel 11, which is a display panel, and a backlight unit 12 (an example of a lighting device), which is an external light source. The liquid crystal panel 11 and the backlight unit 12 are held together by a frame-shaped bezel 13 as illustrated in FIG. 2.

“The display surface 11a is set along the vertical direction” is not limited to a condition that the display surface 11a is set parallel to the vertical direction. The display surface 11a may be set along a direction closer to the vertical direction than the horizontal direction. For example, the display surface 11a may be 0° to 45° slanted to the vertical direction, preferably 0° to 30° slanted.

Next, the liquid crystal panel 11 and the backlight unit 12 included in the liquid crystal display device 10 will be explained. The liquid crystal panel (a display panel) 11 has a rectangular plan view and includes a pair of transparent glass substrates bonded together with a predetermined gap therebetween and liquid crystals sealed between the substrates. On one of the glass substrates, switching components (e.g., TFTs), pixel electrodes and an alignment film are arranged. The switching components are connected to gate lines and the source lines that are perpendicular to each other. The pixel electrodes are connected to the switching components. On the other glass substrate, color filters including R (red) G (green) B (blue) color sections in predetermined arrangement, a counter electrode and an alignment film are arranged. Polarizing plates are arranged on outer surfaces of the glass substrates, respectively.

Next, the backlight unit 12 will be explained in detail. As illustrated in FIG. 3, the backlight unit 12 includes a chassis 14, an optical member 15, LEDs 16 (light emitting diodes), LED boards 17 and light guide plates 18. The chassis 14 has a box-like overall shape and an opening on the front side (the liquid crystal panel 11 side, the light output side). The optical member 15 is arranged so as to cover the opening. The LEDs 16 are light sources arranged inside the chassis 14. The LEDs 16 are mounted on the LED boards 17. Rays of light emitted from the LEDs 16 are directed to the optical member 15 by the light guide plates 18. The backlight unit 12 further includes a support member 19, a holddown member 20 and heat sinks 21. The support member 19 holds diffusers 15a and 15b included in the optical member 15 from the rear side. The holddown member 20 holds down the diffusers 15a and 15b from the front side. The heat sinks 21 are provided for dissipation of heat generated while the LEDs 16 emit light.

Next, components of the backlight unit 12 will be explained in detail. The chassis 14 is made of metal and has a shallow-box-like overall shape (or a shallow-bowl-like overall shape) with the opening on the front-surface side. The chassis 14 includes a bottom plate 14a, side plates 14b and support plates 14c. The bottom plate 14a has a rectangular shape similar to the liquid crystal panel 11. The side plates 14b rise from the respective edges of the bottom plate 14a. The support plates 14c project outward from the respective end edges of the side plates 14b. The long-side direction and the short-side direction of the chassis 14 correspond to the horizontal direction (the X-axis direction) and the vertical direction (the Y-axis direction), respectively. The support plates 14c of the chassis 14 are configured such that the support member 19 and the holddown member 20 are placed thereon, respectively, from the front-surface side. Each support plate 14c holds the bezel 13, the support member 19 and the holddown member 20 together with screws. A mounting structure (not shown) for mounting the LED board 17 and the light guide plate 18 is provided on the bottom plate 14a. The mounting structure may be a screw hole in which a screw member is screwed up or a screw insertion hole through which a screw member is inserted when the LED board 17 or the light guide plate 18 is mounted with screw members.

The optical member 15 is arranged between the liquid crystal panel 11 and the light guide plates 18. It includes the diffusers 15a and 15b arranged on the light guide plate 18 side, and an optical sheet 15c arranged on the liquid crystal panel 11 side. Each of the diffusers 15a and 15b includes a transparent resin base material with a predefined thickness and a large number of diffusing particles scattered in the base material. The diffusers 15a and 15b have functions of diffusing light that passes therethrough. The diffusers 15a and 15b having the same thickness are placed on top of each other. The optical sheet 15c is a thin sheet having a smaller thickness than that of the diffusers 15a and 15b. The optical sheet 15c includes three sheets placed on top of each other, more specifically, a diffusing sheet, a lens sheet and a reflection-type polarizing sheet arranged in this order from the diffuser 15a (15b) side (i.e., from the rear-surface side).

The support member 19 and the holddown member 20 are formed in a frame-like shape so as to follow outer peripheral edge portions of the liquid crystal panel 11 and the optical member 15. The support member 19 is placed directly on the support plate 14c of the chassis 14 and supports outer peripheral edge portions of the diffuser 15b of the optical member on a rear-surface side. The holddown member 20 is placed on the support member 19 and holds down the diffuser 15a of the optical member 15 on the front-surface side from the front-surface side. Therefore, the two diffusers 15a, 15b are held between the support member 19 and the holddown member 20. The holddown member 20 supports the outer peripheral edge portions of the liquid crystal panel 11 from the rear-surface side. The liquid crystal panel 11 is held between the holddown member 20 and the bezel 13 that holds down the outer peripheral edge portions of the liquid crystal panel 11 from the front-surface side. The bezel 13 is also formed in a frame-like shape so as to surround a display area of the liquid crystal panel 11 like the support member 19 and the holddown member 20.

The heat sink 21 is made of synthetic resin or metal having high thermal conductivity and formed in a sheet-like shape. The heat sink 21 extends along an inner surface of the bottom plate 14a of the chassis 14. The heat sink 21 is placed between the bottom plate 14a of the chassis 14 and the LED board 17.

The LED board 17 is made of synthetic resin and the surface thereof is in white that provides high light reflectivity. The LED board 17 extends over the bottom plate 14a of the chassis 14 and is placed on the heat sink 21. Wiring patterns that are metal films are formed on each LED board 17 and the LEDs 16 are mounted in predetermined locations on the LED board 17. The LED board 17 is connected to an external control board, which is not illustrated in the figures. The control board is configured to feed currents for turning on the LEDs 16 and to perform driving control of the LEDs 16. Amounting structure (not illustrated) for mounting the LED board 17 to the chassis 14 is provided on the LED board 17. In mounting with screw members, screw holes in which the screw members are screwed up or screw insertion holes through which the screw members are inserted are provided as the mounting structure. Such a mounting structure is also provided on the light guide plate 18 and the same explanation thereof will be omitted.

Next, the LEDs 16 and the light guide plates 18 of the present embodiment will be explained. A set of the corresponding LED 16 and light guide plate 18 forms a unit light emitter as illustrated in FIGS. 2 to 4. A number of the unit light emitters are arranged two-dimensionally in series along the display surface 11a (in the X-axis direction and in the Y-axis direction) (in a plane arrangement).

Specifically, the LEDs 16 are surface-mounted to the LED board 17, that is, the LEDs 16 are surface-mount LEDs. A number of LEDs 16 are arranged in a planar grid pattern in the X-axis direction and in the Y-axis direction on a front surface of the LED board 17. The light guide plates 18 are provided between the LED board 17 and the diffuser 15b that is on the rear-surface side of the optical member 15. A number of the light guide plates 18 are arranged to correspond to the LEDs 16 respectively in the X-axis direction and in the Y-axis direction, that is, in a grid pattern (horizontally and vertically, with being tiled). The arrangement pitch (the arrangement interval) of the LEDs 16 on the LED board 17 corresponds to the arrangement pitch of the light guide plates 18. The light guide plates 18 are arranged so as not to overlap the adjacent light guide plates 18 in the X-axis direction and in the Y-axis direction in a plan view. The light guide plates 18 are arranged to have a predetermined gap (space, clearance) therebetween and an air layer AR (having a lower reflective index relative to the light guide plate 18) is provided in the gap. Next, each structure of the LED 16 and the light guide plate 18 will be explained.

As illustrated in FIGS. 4 and 5, each LED 16 has a block-like overall shape that is a rectangular shape in a plane view. The LED 16 is arranged such that the long-side direction matches the X-axis direction and the short side direction matches to the Y-axis direction. As illustrated in FIG. 5, the LED 16 includes a board 16a that is to be fixed to the LED board 17, an LED chip 16b mounted on the board 16a, and a resin member 16c for sealing the LED chip 16b. The rear surface of the board 16a is soldered to a land on the LED board 17. The LED 16 mounted on the board 16a includes three different kinds of the LED chips 16b with different main emission wavelengths. Specifically, each LED chip 16b emits a single color of light of red (R), green (G) or blue (B). The rays of light emitted from each LED chip 16b is mixed with each other while traveling through the light guide plate 18 and white light is generated. The resin member 16c fixes the LED chip 16b to the board 16a, and is substantially transparent and is not an optical obstacle in the path of rays of light emitted from the LED chip 16b.

The LED 16 includes a light emitting surface 16d that is slanted to the X-axis and also slanted to the Z-axis (slanted to a light exit surface 18c and also slanted to a surface perpendicular to the light exit surface 18c). Specifically, the LED 16 has a cross section of substantially a right triangle that is taken along an X-Z plane and the hypotenuse of the right triangle is the light emitting surface 16d. The boards 16a extend along two sides of the right triangle except for the hypotenuse respectively and are formed to have substantially an L-shaped cross section. Therefore, the light emitting surface 16d is slanted to face the diagonally right upward in FIG. 5 (the light exit surface 18c side and the another end side of the light guide plate 18). The light emitting surface 16d extends in the Y-axis direction and is slanted at a constant angle (slanted angle) over an entire area in the Y-axis direction. The slanted angle of the light emitting surface 16d with respect to the X-axis direction and the Z-axis direction is determined by an X-axial dimension and a Z-axial dimension of the board 16a (LED 16). However, the slanted angle is not limited to the one illustrated in the drawings and may be altered as necessary.

The light axis LA of rays of light emitted from the LED 16 substantially matches the normal line to the light emitting surface 16d. Therefore, the light axis LA is also slanted to the X axis and Z axis like the light emitting surface 16d. Rays of light emitted from the light emitting surface 16d of the LED 16 radiate three-dimensionally around the light axis LA in a specific angle range. The directivity thereof is higher than cold cathode tubes. Namely, angle distributions of the LED 16 shows a tendency that the emission intensity of the LED 16 is significantly high along the light axis LA and sharply decreases as the angle to the light axis LA increases. Therefore, rays of light emitted from the light emitting surface 16d are mostly directed to the diagonal right upward along the light axis LA.

The light guide plate 18 is made of substantially transparent (i.e., having high light transmission capability) synthetic resin (e.g. polycarbonate), a reflective index of which is significantly higher than that of air. As illustrated in FIGS. 4 and 5, the light guide plate 18 has a plate-like shape having a rectangular overall plan view. The long-side direction of the light guide plate 18 matches the X-axis direction and the short-side direction thereof matches the Y-axis direction. As illustrated in FIG. 5, the light guide plate 18 is provided between the LED board 17 and the diffuser 15b and mounted to the LED board 17 to cover the LED 16 mounted on the LED board 17 from the front-surface side. In other words, the LED 16 is arranged just under the light guide plate 18. An LED housing space 18a for housing the LED 16 therein is formed on a rear surface of the light guide plate 18 that faces the LED board 17. The LED housing space 18a is provided in a left side end portion (one end portion) of two end portions of the light guide plate 18 in the X-axis direction (one direction along a light exit surface 18c) as illustrated in FIGS. 4 and 5. The LED housing space 18a has a size slightly larger than an overall size of the LED 16. Therefore, when the LED 16 is in the LED housing space 18a, the LED 16 is placed in the left end portion of the light guide plate 18 in FIGS. 4 and 5 and a predetermined gap is provided between an inner surface forming the LED housing space 18a and an outer surface of the LED 16. The surfaces are facing each other. The LED housing space 18a is open on the rear-surface side (the side opposite from the light exit surface 18c side) and open on the left side in FIG. 5.

An inner surface forming the LED housing space 18a that faces the light emitting surface 16d of the LED 16 is a light entrance surface 18b. The rays of light emitted from the light emitting surface 16d enter the light entrance surface 18b. A surface of the light guide plate 18 on the front-surface side that faces the diffuser 15b is a light exit surface 18c from which the rays of light traveling through the light guide plate 18 exit. The light exit surface 18c is substantially parallel to an X-Y plane and substantially a flat surface macroscopically and microscopically. The light exit surface 18c is an interface with an air layer AR that is provided between the light exit surface 18c and the diffuser 15b (the optical member) provided adjacent to the light exit surface 18c in the Z-axis direction. Each side end surface 18 is an interface with an air layer AR that is provided in a space between the adjacent light guide plates 18 in the X-axis direction and the Y-axis direction. Therefore, even if the rays of light traveling through the light guide plate 18 strike the light exit surface 18c and each side end surface 18d that is an interface with the external air layer AR, scattered reflection of light does not occur. As long as incident angles of light that strikes the light exit surface 18c and each side end surface 18d are larger than a critical angle, the rays of light are totally reflected and travel through the light guide plate 18 and do not leak from the light exit surface 18c and each side end surface 18d to outside (the air layer AR). “Macroscopically” is referred to a condition in that a specific shape is easily recognized by viewing an outer appearance, and “microscopically” is referred to a condition in that a specific shape is less likely to be recognized by viewing an outer appearance and a specific shape is recognized by using a magnifying glass or a microscope.

The light entrance surface 18b will be explained again. The light entrance surface 18b is parallel to the light emitting surface 16d of the LED 16 and slanted to the X axis and also slanted to the Z axis (slanted to the light exit surface 18c and also slanted to a surface perpendicular to the light exit surface 18c). Specifically, peripheral portions forming the LED housing space 18a has a cross section of substantially a right triangle so as to match the cross section of the LED 16 taken along the X-Z plane. The hypotenuse of the right triangle is the light entrance surface 18b. The light entrance surface 18b is substantially parallel to the light emitting surface 16d and slanted to face diagonally downward left in FIG. 5. The light entrance surface 18b extends along the Y-axis direction and is slanted at a constant slanted angle over an entire area in the Y-axis direction. The slanted angle of the light entrance surface 18b to the X-axis direction or the Z-axis direction is set to be substantially equal to the slanted angle of the light emitting surface 16d.

On a surface of the light guide plate 18 on the rear-surface side, that is an area of the surface of the light guide plate 18 opposite from the light exit surface 18c excepting for the LED housing space 18a (hereinafter, referred to as a mounting surface 18e on which the reflection sheet 22 is mounted), a scattering structure 23 is provided and the reflection sheet 22 for reflecting light toward the light exit surface 18c side is provided. The scattering structure 23 scatters the light traveling through the light guide plate 18 and the reflection sheet 22 directs the light toward the light exit surface 18c. Accordingly, the rays of light are directed to the light exit surface 18c and strike the light exit surface 18c at the incident angles smaller than the critical angle and the rays of light entering the light entrance surface 18b exit indirectly through the light exit surface 18c. The reflection sheet 22 mounting surface 18e is slanted to face diagonally downward right in FIG. 5. Namely, the mounting surface 18e is slanted to face an opposite side from the light entrance surface 18b in the X-axis direction. The mounting surface 18e and the light entrance surface 18b form an obtuse angle. The light guide plate 18 is formed to be tapered such that the thickness reduces in a continuous and gradual manner as it is from the interface between the light entrance surface 18b and the reflection sheet 22 mounting surface 18e toward the right end portion in FIG. 5 (an end portion of the light guide plate 18 opposite from the LED 16).

The scattering structure 23 includes a large number of microscopic projections 23a that are molded by a molding die (not illustrated) that is used for molding the light guide plate 18 with resin. The projections 23a are formed on the reflection sheet 22 mounting surface 18e. As illustrated in FIG. 4, the projections 23a are formed to have a cross section of an angled shape (substantially a triangular cross section) and extend in the Y-axis direction and a large number of the elongated projections 23a are arranged parallel to each other in the X-axis direction.

An arrangement pitch of the projections 23a is set in an irregular manner. The arrangement pitch becomes smaller from the left side end portion toward the right side end portion in FIG. 5. Namely, the farther from the LED 16, the smaller the arrangement pitch becomes. Accordingly, the projections 23a are formed in a gradational arrangement. In other words, the closer to the LED 16, the lower the distribution density of the projections 23a in the reflection sheet 22 mounting surface 18e plane becomes, and the farther from the LED 16, the higher the distribution density becomes, that is, the projections 23a are formed in a regular manner. The rays of light traveling through the light guide plate 18 to be directed to the reflection sheet 22 mounting surface 18e strike the sloped surfaces of the projections 23a and scattered. The degree of light scattering is relatively low on the side closer to the LED 16 in the X-axis direction along the mounting surface 18e and the degree of light scattering is relatively high on the side farther from the LED 16. The degree of light scattering increases in a gradual and continuous manner as it is farther from the LED 16 and it is lowered in a gradual and continuous manner as it is closer to the LED 16. Accordingly, the rays of light are relatively less likely to be directed to the light exit surface 18c in the area of the mounting surface 18e closer to the LED 16 from which a relatively greater amount of rays of light emit. The rays of light are likely to be directed to the light exit surface 18c in the area of the mounting surface 18e farther from the LED 16 from which a relatively small amount of rays of light emit. This achieves the uniform (equalized) in-plane distribution of the amount of rays of light directed from the reflection sheet 22 and the mounting surface 18e to the light exit surface. The gaps between the reflection sheet 22 and the projections 23a formed on the mounting surface 18e are air layers AR.

The liquid crystal display device 10 of the present embodiment is structured as mentioned before, and an operation thereof will be explained. Power of the liquid crystal display device 10 is turned onto light each LED 16. Rays of light emitted from the light emitting surface 16d of the LED 16 strike the corresponding light entrance surface 18b of the light guide plate 18 as illustrated in FIG. 5. The rays of light travel through the light guide plate 18 and exit through the light exit surface 18c.

Specifically, the rays of light entering the light entrance surface 18b are mostly directed to the light exit surface 18c along the light axis LA of rays of light emitted from the LED 16. The slanted angle of the light emitting surface 16d and the light entrance surface 18b is set so that incident angles of the rays of light directed along the light axis LA and striking the light exit surface 18c are greater than the critical angle.

Therefore, most of the rays of light entering the light entrance surface 18b is totally reflected by the interface between the light exit surface 18c and the external air layer AR and directed to the rear-surface side, that is the reflection sheet 22 side.

The rays of light directed to the reflection sheet 22 side are scattered by the scattering structure 23 and reflected by the reflection sheet 22 to the light exit surface 18c again. In such a case, the rays of light that are not totally reflected by the light exit surface 18c (incident angles of the rays of light striking the light exit surface 18c are smaller than a critical angle) exit from the light exit surface 18c to the outside on the front-surface side. However, the rays of light that are totally reflected by the light exit surface 18c (incident angles of the rays of light striking the light exit surface 18c are greater than a critical angle) are returned to the reflection sheet 22 side again. This operation is repeated so that the rays of light travel through an entire area of the light guide plate 18 and eventually exit from the light exit surface 18c to the outside on the front-surface side. In FIG. 5, the rays of light traveling through the light guide plate 18 are described by arrows.

The degree of light scattering by the projections 23a of the scattering structure provided on the reflection sheet 22 mounting surface 18e becomes lower as it is closer to the LED 16, and it becomes higher as it is farther from the LED 16. Therefore, the rays of light are less likely to be directed to the light exit surface in the area of the light guide plate 18 through which a relatively great amount of rays of light travel, and the rays of light are likely to be directed to the light exit surface in the area of the light guide plate 18 through which a relatively small amount of rays of light travel. Accordingly, the in-plane distribution of the amount of rays of light directed from the reflection sheet 22 and the mounting surface 18e to the light exit surface 18c is unified. The in-plane distribution is unified in the reflection sheet 22 and the mounting surface 18e.

As mentioned before, the light emitting surface 16d and the light entrance surface 18b are provided to be slanted to the X axis and also slanted to the Z axis by a predetermined angle. Accordingly, the rays of light entering the light entrance surface 18b along the light axis LA strike the area of the light exit surface 18c that is just above the light entrance surface 18b and first total reflection is performed. Therefore, compared to the case in which the light emitting surface and the light entrance surface are provided to be perpendicular to the X-axis direction and the Y-axis direction (parallel to the Z-axis direction) and the light axis is parallel to the X-axis direction, the first total reflection is performed in a position closer to the LED 16. This increases the average number of reflection times of the rays of light traveling through the light guide plate 18 and sufficiently increases the light path length of the rays of light traveling through the light guide plate 18. Therefore, single color light emitted from each LED chip 16b of the LED 16 is mixed with each other sufficiently while traveling through the light guide plate 18 to generate white light. Then, the white light exits from the light exit surface 18c, and therefore color unevenness is less likely to be caused.

As explained above, the backlight unit 12 of the present embodiment includes the LED 16 having the light emitting surface 16d and the light guide plate 18 having the light entrance surface 18b and the light exit surface 18c. The light entrance surface 18b is provided to face the light emitting surface 16d and rays of light emitted from the light emitting surface 16d enter the light entrance surface 18b. The rays of light exit from the light exit surface 18c. A number of the light guide plates 18 are arranged parallel to each other in the direction along the light exit surface 18c. The light emitting surface 16d and the light entrance surface 18b are slanted to a surface perpendicular to the light exit surface 18c.

With this configuration, the rays of light emitted from the light emitting surface 16d of the LED 16 and entering the light entrance surface 18b of the light guide plate 18 are totally reflected by an interface between the light guide plate 18 and the external space and travel through the light guide plate 18. Then, the rays of light exit from the light exit surface 18c. The light emitting surface 16d and the light entrance surface 18b are slanted to a surface perpendicular to the light exit surface 18c. Therefore, compared to the case in which the light emitting surface and the light entrance surface are provided to be perpendicular to the light exit surface 18c, the rays of light traveling through the light guide plate 18 are able to be angled so that the number of reflection times at the interface relatively increases. This ensures a sufficient light path length of rays of light traveling through the light guide plate 18.

To ensure the light path length of rays of light traveling through the light guide plate, the light guide plate has included the light guide portion from which the rays of light do not exit. However, if the light guide portion is bare on the front-surface side, it may be recognized as a dark point. Therefore, the adjacent light guide plate overlaps the light guide portion on the front-surface side. However, if the light guide plates overlap each other, the following problem may occur. When malfunction is found in any one of the LEDs in the manufacturing process or in repairing, not only the light guide plate corresponding to the LED having malfunction but also all the light guide plates that overlap directly or indirectly the light guide plate corresponding to the LED having malfunction are required to be removed. The operation is quite troublesome.

In the present embodiment, a sufficient light path length of rays of light traveling through the light guide plate 18 is ensured without providing the light guide portion. Therefore, the adjacent light guide plates 18 are not required to overlap each other. If malfunction is found in any one of the LEDs 16 in the manufacturing process or repairing, only the light guide plate 18 corresponding to the LED 16 having malfunction is removed to solve the problem. Therefore, the operation is quite easy.

The light emitting surface 16d is slanted to face the light exit surface 18c with respect to a plane perpendicular to the light exit surface 18c and the light entrance surface 18b is provided to parallel to the light emitting surface 16d. With this configuration, the rays of light emitted from the light emitting surface 16d and entering the light entrance surface 18b are angled to be temporally directed to the light exit surface 18c and totally reflected by an interface with the external space.

The LED 16 is arranged on one of two end portions of the light guide plate 18 in one direction along the light exit surface 18c. With this configuration, the light emitting surface 16d of the LED 16 that is arranged on the one end of the light guide plate 18 is slanted to face the light exit surface 18c and then, the light emitting surface 16d is slanted to face another one of the ends of the light guide plate 18. Accordingly, the rays of light emitted from the light emitting surface 16d are effectively guided to the another end of the light guide plate 18.

The scattering structure 23 for scattering the rays of light and the reflection sheet 22 for reflecting the rays of light to the light exit surfaces 18c side are provided on a surface of the light guide plate 18 that is opposite from the light exit surface 18c (the mounting surface 18e). With this configuration, when the rays of light traveling through the light guide plate 18 strike a surface opposite from the light exit surface 18c, the rays of light are scattered by the scattering structure 23 and the scattered rays of light are reflected by the reflection sheet 22 to the light exit surface 18c side. This improves light use efficiency.

The scattering structure 23 is configured such that the degree of light scattering increases in a continuous and gradual manner as it is farther from the LED 16. The amount of rays of light traveling through the light guide plate 18 is relatively greater in an area closer to the LED 16 than in an area farther from the LED 16 in the direction parallel to the light exit surface 18c. Therefore, the degree of light scattering by the scattering structure 23 is relatively lowered in the area closer to the LED 16 having a large amount of rays of light to reduce the amount of rays of light reflected by the reflection sheet 22. The degree of light scattering is relatively increased in the area farther from the LED 16 having a small amount of rays of light to increase the amount of rays of light reflected by the reflection sheet 22. Accordingly, uniform in-plane brightness distribution of the amount of rays of light reflected by the reflection sheet 22 is achieved. Therefore, the uneven brightness is less likely to be caused.

The scattering structure 23 includes a large number of microscopic projections 23a. With this configuration, a large number of projections 23a effectively scatter rays of light. “Microscopic” is referred to a condition in that a specific shape is less likely to be recognized by viewing an outer appearance and a specific shape is recognized by using a magnifying glass or a microscope.

The light source is the LED 16. With this configuration, improved brightness is achieved.

The LED 16 includes a number of different kinds of the LED chips 16b with different main emission wavelengths. With this configuration, a sufficient light path length of rays of light traveling through the light guide plate 18 is ensured, and therefore rays of light emitted from each LED chip 16b are mixed effectively while traveling through the light guide plate 18.

### Second Embodiment

Next, the second embodiment of the present invention will be explained with reference to FIGS. 6 and 7. In the second embodiment, a configuration of the LED 16A and the light guide plate 18A is altered. The same components as the first embodiment will be indicated with the same symbols. The symbols with the letter A are used for referring to the same parts as the first embodiment. The same configuration, functions and effects will not be explained.

As illustrated in FIGS. 6 and 7, the LED 16A extends straight in the Y-axis direction and has a cross section of substantially an isosceles triangle taken along the X-Z plane. A length of the LED 16A (dimension in the Y-axis direction) is substantially equal to or slightly smaller than a dimension of the light guide plate 18A in the Y-axis direction. The LED 16A includes three different kinds of LED chips 16bA with different main emission wavelengths of R, G, B in substantially a middle portion in the X-axis direction. A large number of the LED chips 16bA are arranged in a predetermined order straight along the Y-axis direction that is one direction on the light exit surface 18cA. Thus, the LED 16A of the present embodiment forms an array by arranging different kinds of LED chips 16bA in one direction. Accordingly, the LED 16A forms a linear light source such as a cold cathode tube.

The LED 16A includes two light emitting surfaces 16d1, 16d2 on two sides of a top portion 16e. Each of the light emitting surfaces 16d1, 16d2 faces in a different side. Specifically, the left-side first light emitting surface 16d1 in FIG. 6 faces diagonally upward left side and the right-side second light emitting surface 16d2 in FIG. 6 faces diagonally upward right side. The first light emitting surface 16d1 and the second light emitting surface 16d2 extend in the Y-axis direction that is an arrangement direction in which the LED chips 16bA are arranged. Each of the first light emitting surface 16d1 and the second light emitting surface 16d2 is slanted at a constant angle over an entire area in the Y-axis direction. A first light axis LA1 that matches a normal line to the first light emitting surface 16d1 and a second light axis LA2 that matches a normal line to the second light emitting surface 16d2 are slanted to the X axis and the Z axis and cross each other.

The light guide plate 18A includes three LED housing recesses 18aA each of which houses the LED 16A. The LED housing recesses 18aA are provided with a predetermined gap therebetween in the X-axis direction. Therefore, corresponding three LEDs 16A are arranged for the single light guide plate 18A of the present embodiment. Each LED housing recess 18aA has a cross section of substantially an isosceles triangle taken along the X-Z plane so as to follow the cross section of the LED 16A. The inner surfaces of the LED housing recess 18aA are light entrance surfaces 18b1, 18b2 that face the light emitting surfaces 16d1, 16d2 respectively. Planes on the light entrance surfaces 18b1, 18b2 cross each other and each of the light entrance surfaces 18b1, 18b2 is slanted to the X axis and the Z axis. Specifically, the left-side first light entrance surface 18b1 in FIG. 6 is parallel to the first light emitting surface 16d1 and the right-side second light entrance surface 18b2 is parallel to the second light emitting surface 16d2. Each of the light entrance surfaces 18b1, 18b2 extends in the Y-axis direction and is slanted at a constant angle over an entire area in the Y-axis direction. The slanted angle of each light entrance surface 18b1, 18b2 with respect to the X-axis direction and the Z-axis direction is substantially equal to each other and substantially equal to the slanted angle of the light emitting surfaces 16d1, 16d2.

A reflection sheet 22A mounting surface 18eA of the light guide plate 18 is substantially parallel to the light exit surface 18cA over an entire area. A scattering structure 23A formed on the reflection sheet 22A mounting surface 18eA is configured as follows. As illustrated in FIG. 7, a large number of microscopic projections 23aA of the scattering structure 23A are arranged in a gradational arrangement as follows. The closer to the LED 16A, the lower the distribution density of the projections 23aA becomes (the greater the arrangement pitch becomes), and the farther from the LED 16A, the higher the distribution density of the projections 23aA becomes (the smaller the arrangement pitch becomes). Specifically, in the area between the adjacent LEDs 16A on the reflection sheet 22A mounting surface 18eA, the distribution density of the projections 23aA is highest in a middle portion between the LEDs 16A. The projections 23a are arranged so that the distribution density reduces in a continuous and gradual manner as is closer to the LED 16A from the middle portion. With this configuration, the uniform in-plane brightness distribution of the amount of rays of light directed from the reflection sheet 22A to the light exit surface 18cA is achieved.

The LED 16A includes the two light emitting surfaces 16d1, 16d2 that face different directions and are slanted to the X-axis direction and the Z-axis direction. The light guide plate 18A includes the two light entrance surfaces 18b1, 18b2 corresponding to the light emitting surfaces 16d1, 16d2. Therefore, the surfaces are angled so that the rays of light emitted from each light emitting surface 16d1, 16d2 and entering the corresponding light entrance surface 18b1, 18b2 first strike the light exit surface 18cA and are totally reflected to the reflection sheet 22A side. Accordingly, the number of reflection times of the rays of light traveling through the light guide plate 18A increases and a sufficient light path length is obtained.

As explained before, according to the present embodiment, the LED 16A includes the two light emitting surfaces 16d1, 16d2 on the two sides of the top portion 16e. Each of the light emitting surfaces 16d1, 16d2 faces in a different side. The light guide plate 18A includes the light entrance surfaces 18b1, 18b2 so as to face the light emitting surfaces 16d1, 16d2 respectively. With this configuration, the rays of light emitted from the two light emitting surfaces 16d1, 16d2 provided on the two sides of the top portion 16e to face in the different sides enter the two light entrance surfaces 18b1, 18b2 that face the light emitting surfaces 16d1, 16d2 respectively. Accordingly, the rays of light entering the light entrance surfaces 18b1, 18b2 travel through the light guide plate 18A effectively.

The light emitting surfaces 16d1, 16d2 and the light entrance surfaces 18b1, 18b2 are slanted to a surface perpendicular to the light exit surfaced 18cA at substantially a same angle. With this configuration, the rays of light emitted from each light emitting surface 16d1, 16d2 and entering the corresponding light entrance surface 18b1, 18b2 travel through the light guide plate 18A evenly.

The LED 16A includes a large number of the LED chips 16bA that are arranged in straight along one direction on the light exit surface 18cA. The light emitting surfaces 16d1, 16d2 extend in the arrangement direction in which the LED chips 16bA are arranged. With this configuration, the LED 16A including an array of the LED chips 18bA is preferable for a large light guide plate 18A. This reduces the number of the light guide plates 18A that are used for the device and this also reduces the number of assembling processes and a cost.

The three (a number of) LEDs 16A are provided for one light guide plate 18A. With this configuration, brightness is improved.

### Other Embodiments

The present invention is not limited to the above embodiments explained in the above description. The following embodiments may be included in the technical scope of the present invention, for example.

(1) The slanted angle of the light emitting surfaces and the light entrance surfaces with respect to the Z-axis or the x-axis may be altered as necessary. In the above embodiments, the light emitting surfaces are parallel to the light entrance surface. However, the light emitting surfaces and the light entrance surfaces may be relatively slanted to each other.

(2) As a modification of the first embodiment, a number of the LEDs may be arranged for one single light guide plate. Specifically, the LEDs may be provided on either side of the light guide plate and the light emitting surface of each of the two LEDs faces a middle portion of the light guide plate. In such a case, the degree of scattering of the scattering structure may be set in a gradational manner so that the degree of scattering increases as it is closer to the middle portion of the light guide plate and the degree of scattering reduces as it is closer to the two side ends of the light guide plate.

(3) In the first embodiment, the LED housing space is open on two surfaces including the rear surface and the side surface of the light guide plate. However, the LED housing space may be open only on the rear surface of the light guide plate.

(4) In the first embodiment, the reflection sheet mounting surface is slanted. However, the reflection sheet mounting surface may be parallel to the light exit surface.

(5) The array of LEDs of the second embodiment may be used as the LED of the first embodiment.

(6) In the second embodiment, three arrays of the LEDs are arranged parallel to each other. However, the number of the LEDs may be altered as necessary.

(7) In the second embodiment, a number of sets each including the three different LED chips with different main emission wavelengths are arranged parallel to each other. However, only one set of the three kinds of LED chips may be arranged.

(8) The arrangement position of the LED may be altered as necessary.

(9) In the above embodiments, the scattering structure includes a number of microscopic projections. The scattering structure may include a number of microscopic recesses. The resin molding is described as a specific molding method for forming the scattering structure, however, microscopic recesses or projections may be formed by coating fine powders such as silica. As another method, a blast processing may be performed on the reflection sheet mounting surface to form the microscopic recesses. With any of the methods, the recesses or the projections may be arranged in an irregular manner.

(10) In the above embodiments, the distribution density (the degree of scattering) of the microscopic projections provided as the scattering structure is changed in a continuous and gradual manner. However, the distribution density of the microscopic recesses or projections may be changed in a step-by-step and sequential manner. The distribution density of the microscopic recesses or projections may be uniform.

(11) In the above embodiments, the reflection sheet is provided for every light guide plate separately. However, a single reflection sheet maybe provided for a number of the light guide plates. In such a case, the reflection sheet may be provided in an area between the adjacent light guide plates.

(12) In the above embodiments, the air layers are used as the low reflective index layers provided between the adjacent light guide plates. A low reflective index layer made of a low reflective index material may be provided in each gap between the light guide plates.

(13) In the above embodiments, each LED and each light guide plate has a rectangular shape in a plan view. However, each LED and each light guide plate may have a square shape in a plan view.

(14) In the above embodiments, the LEDs and the light guide plates (unit light emission members) are arranged parallel to each other two-dimensionally within the chassis. However, they may be arranged parallel to each other one-dimensionally. Specifically, the LED and the light guide plates may be arranged parallel to each other only in the vertical direction or the LED and the light guide plates may be arranged parallel to each other only in the horizontal direction. Only one set of the LED and the light guide plate may be provided.

(15) In the above embodiments, each LED includes three different LED chips configured to emit respective colors of RGB. However, LEDs each including a single LED chip configured to emit a single color of blue or violet and each configured to emit white light using fluorescent material may be used.

(16) In the above embodiments, each LED includes three different LED chips configured to emit respective colors of RGB. However, LEDs each including three different LED chips configured to emit respective colors of cyan (C), magenta (M) and yellow (Y) may be used.

(17) In the above embodiments, the LEDs are used as point light sources. However, point light sources other than LEDs can be used.

(18) The optical member may be configured differently from the above embodiments. Specifically, the number of diffusers or the number and the kind of the optical sheets can be altered as necessary. Furthermore, a plurality of optical sheets in the same kind may be used.

(19) In the above embodiments, the liquid crystal panel and the chassis are held in the vertical position with the short-side direction thereof aligned with the vertical direction. However, the liquid crystal panel and the chassis may be held in the vertical position with the long-side direction thereof aligned with the vertical direction.

(20) In the above embodiments, TFTs are used as switching components of the liquid crystal display device. However, the technology described the above can be applied to liquid crystal display devices including switching components other than TFTs (e.g., thin film diode (TFD)). Moreover, the technology can be applied to not only color liquid crystal display devices but also black-and-white liquid crystal display devices.

(21) In the above embodiments, the liquid crystal display device including the liquid crystal panel as a display component is used in the above embodiment. The technology can be applied to display devices including other types of display components.

(22) In the above embodiments, the television receiver including the tuner is used. However, the technology can be applied to a display device without a tuner.

1. A lighting device comprising:
a light source including a light emitting surface; and
a light guide member including a light entrance surface and a light exit surface, the light entrance surface being provided to face the light emitting surface and that light emitted from the light emitting surface enters and the light exit surface through which the light exits, the light emitting surface and the light entrance surface being slanted to a surface perpendicular to the light exit surface.

2. The lighting device according to claim 1, wherein the light emitting surface is slanted to face the light exit surface side with respect to the surface perpendicular to the light exit surface and the light entrance surface is parallel to the light emitting surface.

3. The lighting device according to claim 2, wherein the light source is provided on one of two side ends of the light guide plate with respect to one direction on the light exit surface.

4. The lighting device according to claim 2, wherein:
the light emitting surface includes two light emitting surfaces that are provided on two sides of a top portion of the light source respectively to face in a different side; and
the light entrance surface includes two light entrance surfaces to face the two light emitting surfaces respectively.

5. The lighting device according to claim 4, wherein the two light emitting surfaces and the two light entrance surfaces are slanted to the surface perpendicular to the light exit surface at substantially a same angle.

6. The lighting device according to claim 1, wherein:
the light source includes a number of light emitting components that are arranged in straight along one direction on the light exit surface; and
the light emitting surface extends in an arrangement direction in which the light emitting components are arranged.

7. The lighting device according to claim 1, further comprising:
a scattering structure provided on a surface of the light guide member opposite from the light exit surface and configured to scatter light; and
a reflection member provided on the surface of the light guide member opposite from the light exit surface and configured to reflect light to the light exit surface side.

8. The lighting device according to claim 7, wherein the scattering structure is configured so that a degree of light scattering increases in a continuous and gradual manner as is getting farther from the light source along the light exit surface.

9. The lighting device according to claim 7, wherein the scattering structure includes one of a number of microscopic recesses and a number of microscopic projections.

10. The lighting device according to claim 1, wherein the light source is an LED.

11. The lighting device according to claim 10, wherein the LED includes a number of kinds of LED chips having different main emission wavelengths.

12. The lighting device according to claim 1, wherein the light source includes a number of light sources and the light sources are provided for the one light guide member.

13. A display device comprising:
the lighting device according to claim 1; and
a display panel configured to provide display using light from the lighting device.

14. The display device according to claim 13, wherein the display panel is a liquid crystal panel including liquid crystals sealed between a pair of substrates.

15. A television receiver comprising the display device according to claim 13.
